(19) United States
(12) Patent Application Publication
(10) Pub. No.: US 2024/0413169 A1
(43) Pub. Date: Dec. 12, 2024

(54) DISPLAY PANEL

(71) Applicant: Guangzhou China Star Optoelectronics Semiconductor Display Technology Co., LTd., Guangzhou (CN)

(72) Inventor: Yunlong LI, Guangzhou (CN)

(73) Assignee: Guangzhou China Star Optoelectronics Semiconductor Display Technology Co., LTd., Guangzhou (CN)

(21) Appl. No.: 18/523,952

(22) Filed: Nov. 30, 2023

(30) Foreign Application Priority Data
Jun. 9, 2023 (CN) 202310686996.5

(51) Int. Cl. H01L 27/12; H01L 25/16

(52) U.S. Cl. CPC H01L 27/124; H01L 25/167

(57) ABSTRACT

The present application discloses a display panel including a pixel region defined in the display panel. The pixel region includes a first region and a second region. The display panel includes a plurality of light emitting devices, a signal input terminal, and a signal connection line. The light emitting devices are disposed in the first region and the second region. The signal input terminal is disposed in the first region, and the signal input terminal is sequentially connected to the light emitting devices of the first region and the light emitting devices of the second region through the signal connection line. Along a direction from a location near the signal input terminal to away from the signal input terminal, because a resistance and a parasitic capacitor exit on the signal connection line, IR drop occurs, the current weakens.

### CROSS REFERENCE TO RELATED APPLICATIONS

This application claims the priority to Chinese Patent Application No. 202310686996.5, filed on Jun. 9, 2023. The entire disclosures of the above application are incorporated herein by reference.

### FIELD OF INVENTION

The present application belongs to a field of display technologies, especially to a display panel.

### BACKGROUND OF INVENTION

A driver substrate of a Mini-LED display panel typically features a plurality of light-emitting chips. Signal connection lines connect to these light-emitting chips. During the process of electrical signal transmission, the signal connection lines introduce factors such as resistance and parasitic capacitance. As a result, the current from the signal input terminal to the signal output terminal gradually weakens, causing a phenomenon known as potential drop (IR drop). This leads to higher brightness in the light-emitting region near the signal input terminal and lower brightness in the region farther away from the signal input terminal, resulting in an uneven display effect on the display panel. Therefore, to address the issue of non-uniform display brightness and improve the uniformity of the display panel, a new type of display panel needs to be proposed. This new panel should allow light-emitting chips both near and away from the signal input terminal to match the current after experiencing IR drop. This, in turn, achieves the goal of enhancing the uniformity of display brightness.

### SUMMARY OF INVENTION

An objective of the present application is to provide a display panel making light emitting devices near the signal input terminal or away from the signal input terminal can match a current after IR drop to improve a uniformity of display brightness of the display panel.

To solve the above technical issue, the present application provides a display panel, comprising a pixel region defined in the display panel, wherein the pixel region comprises a first region and a second region, and the display panel further comprises:
a plurality of light emitting devices disposed in the first region and the second region;
a signal input terminal disposed in the first region; and
a signal connection line, wherein the signal input terminal is sequentially connected to the light emitting devices in the first region and the light emitting devices in the second region through the signal connection line, an area of an orthographic projection of the light emitting devices in the second region on a plane in which the display panel is located is greater than an area of an orthographic projection of the light emitting devices in the first region on the plane in which the display panel is located.

In an embodiment, the first region and the second region are disposed along a first direction, the light emitting devices in the second region are arranged in a quantity N of column sets along the first direction, wherein Nis an integer greater than 1; and
along a direction from a location near the signal input terminal to a location away from the signal input terminal, an area of an orthographic projection of the light emitting devices of a (i−1)^{th} one of the column sets on the plane in which the display panel is located is less than an area of an orthographic projection of the light emitting devices of an i^{th} one of the column sets on the plane in which the display panel is located, wherein i is less than or equal to N.

In an embodiment, the light emitting devices arranged in a quantity M of row sets along a second direction, wherein M is an integer greater than 1, the second direction intersects the first direction; and
along a direction from a location near the signal input terminal to a location away from the signal input terminal, an area of an orthographic projection of the light emitting devices of a (j−1)^{th} one of the row sets on the plane in which the display panel is located is less than an area of an orthographic projection of the light emitting devices of a j^{th} one of the row sets on the plane in which the display panel is located, wherein j is less than or equal to M.

In an embodiment, each of the row sets is at least connected to one of the signal connection lines, and currents of a plurality of the signal connection lines are equal.

In an embodiment, the light emitting device comprises a first light emitting chip, a second light emitting chip, and a third light emitting chip, the first light emitting chip is a red light emitting chip, the second light emitting chip is a green light emitting chip, and the third light emitting chip is a blue light emitting chip; and
an effective light emitting area of the first light emitting chip is greater than an effective light emitting area of the second light emitting chip, and the effective light emitting area of the second light emitting chip is greater than an effective light emitting area of the third light emitting chip.

In an embodiment, the display panel further comprises a driver substrate, the first light emitting chip is disposed on the driver substrate, the second light emitting chip is disposed on the first light emitting chip [symbol] , the third light emitting chip is disposed on the second light emitting chip, and an orthographic projection of the first light emitting chip on the driver substrate, an orthographic projection of the second light emitting chip on the driver substrate, and an orthographic projection of the third light emitting chip on the driver substrate at least overlap one another.

In an embodiment, the display panel further comprises a cathode layer and a cathode wiring, the cathode layer is disposed between the driver substrate and the first light emitting chip, a via hole is defined in each of the light emitting devices, the via hole penetrates the third light emitting chip, the second light emitting chip, and the first light emitting chip and exposes the cathode layer, the cathode wiring is disposed in the via hole, and the cathode wiring is connected to the cathode layer, and a cathode of the first light emitting chip, a cathode of the second light emitting chip, and a cathode of the third light emitting chip is connected to the cathode wiring.

In an embodiment, the display panel further comprises an anode layer, a first anode wiring, a second anode wiring, and a third anode wiring, the anode layer and the cathode layer are disposed insulatively from each other in a same layer, and the first anode wiring, the second anode wiring, the third anode wiring are connected to the anode layer; and
the light emitting devices comprises a first edge, a second edge, and a third edge, an anode of the first light emitting chip is disposed on the first edge and is connected to the first anode wiring, an anode of the second light emitting chip is disposed on the second edge and is connected to the second anode wiring, and an anode of the third light emitting chip is disposed on the third edge and is connected to the third anode wiring.

In an embodiment, the display panel further comprises an anode layer, a first anode wiring, a second anode wiring, and a third anode wiring, the anode layer and the cathode layer are disposed insulatively from each other in a same layer, the first anode wiring, the second anode wiring, and the third anode wiring is connected to the anode layer; and
a hole wall of the via hole at least comprises a first hole wall, a second hole wall, a third hole wall, and a fourth hole wall, the first anode wiring is disposed in the first hole wall and is connected to an anode of the first light emitting chip, the second anode wiring is disposed in the second hole wall and is connected to an anode of the second light emitting chip, the third anode wiring is disposed in the third hole wall and is connected to an anode of the third light emitting chip, and the cathode wiring is disposed in the fourth hole wall

In an embodiment, in overlapping portions, light emitted from the first light emitting chip is emitted out through the second light emitting chip and the third light emitting chip.

The present application also provides a display panel, comprising a pixel region defined in the display panel, wherein the pixel region comprises a first region and a second region, and the display panel further comprises:
a plurality of light emitting devices disposed in the first region and the second region;
a signal input terminal disposed in the first region; and
a signal connection line, wherein the signal input terminal is sequentially connected to the light emitting devices in the first region and the light emitting devices in the second region through the signal connection line, an area of an orthographic projection of the light emitting devices in the second region on a plane in which the display panel is located is greater than an area of an orthographic projection of the light emitting devices in the first region on the plane in which the display panel is located;
wherein the first region and the second region are disposed along a first direction, the light emitting devices in the second region are arranged in a quantity N of column sets along the first direction, wherein N is an integer greater than 1;
wherein along a direction from a location near the signal input terminal to a location away from the signal input terminal, an area of an orthographic projection of the light emitting devices of a (i−1)^{th} one of the column sets on the plane in which the display panel is located is less than an area of an orthographic projection of the light emitting devices of an i^{th} one of the column sets on the plane in which the display panel is located, wherein i is less than or equal to N;
wherein the light emitting devices arranged in a quantity M of row sets along a second direction, wherein M is an integer greater than 1, the second direction intersects the first direction; and
wherein along a direction from a location near the signal input terminal to a location away from the signal input terminal, an area of an orthographic projection of the light emitting devices of a (j−1)^{th} one of the row sets on the plane in which the display panel is located is less than an area of an orthographic projection of the light emitting devices of a j^{th} one of the row sets on the plane in which the display panel is located, wherein j is less than or equal to M.

In an embodiment, each of the row sets is at least connected to one of the signal connection lines, and currents of a plurality of the signal connection lines are equal.

In an embodiment, the light emitting device comprises a first light emitting chip, a second light emitting chip, and a third light emitting chip, the first light emitting chip is a red light emitting chip, the second light emitting chip is a green light emitting chip, and the third light emitting chip is a blue light emitting chip; and
an effective light emitting area of the first light emitting chip is greater than an effective light emitting area of the second light emitting chip, and the effective light emitting area of the second light emitting chip is greater than an effective light emitting area of the third light emitting chip.

In an embodiment, the display panel further comprises a driver substrate, the first light emitting chip is disposed on the driver substrate, the second light emitting chip is disposed on the first light emitting chip [symbol] , the third light emitting chip is disposed on the second light emitting chip, and an orthographic projection of the first light emitting chip on the driver substrate, an orthographic projection of the second light emitting chip on the driver substrate, and an orthographic projection of the third light emitting chip on the driver substrate at least overlap one another.

In an embodiment, the display panel further comprises a cathode layer and a cathode wiring, the cathode layer is disposed between the driver substrate and the first light emitting chip, a via hole is defined in each of the light emitting devices, the via hole penetrates the third light emitting chip, the second light emitting chip, and the first light emitting chip and exposes the cathode layer, the cathode wiring is disposed in the via hole, and the cathode wiring is connected to the cathode layer, and a cathode of the first light emitting chip, a cathode of the second light emitting chip, and a cathode of the third light emitting chip is connected to the cathode wiring.

In an embodiment, the display panel further comprises an anode layer, a first anode wiring, a second anode wiring, and a third anode wiring, the anode layer and the cathode layer are disposed insulatively from each other in a same layer, and the first anode wiring, the second anode wiring, the third anode wiring are connected to the anode layer; and
the light emitting devices comprises a first edge, a second edge, and a third edge, an anode of the first light emitting chip is disposed on the first edge and is connected to the first anode wiring, an anode of the second light emitting chip is disposed on the second edge and is connected to the second anode wiring, and an anode of the third light emitting chip is disposed on the third edge and is connected to the third anode wiring.

In an embodiment, the display panel further comprises an anode layer, a first anode wiring, a second anode wiring, and a third anode wiring, the anode layer and the cathode layer are disposed insulatively from each other in a same layer, the first anode wiring, the second anode wiring, and the third anode wiring is connected to the anode layer; and
a hole wall of the via hole at least comprises a first hole wall, a second hole wall, a third hole wall, and a fourth hole wall, the first anode wiring is disposed in the first hole wall and is connected to an anode of the first light emitting chip, the second anode wiring is disposed in the second hole wall and is connected to an anode of the second light emitting chip, the third anode wiring is disposed in the third hole wall and is connected to an anode of the third light emitting chip, and the cathode wiring is disposed in the fourth hole wall.

In an embodiment, in overlapping portions, light emitted from the first light emitting chip is emitted out through the second light emitting chip and the third light emitting chip.

The present application also provides a display panel, comprising a pixel region defined in the display panel, wherein the pixel region comprises a first region and a second region, and the display panel further comprises:
a plurality of light emitting devices disposed in the first region and the second region;
a signal input terminal disposed in the first region; and
a signal connection line, wherein the signal input terminal is sequentially connected to the light emitting devices in the first region and the light emitting devices in the second region through the signal connection line, an area of an orthographic projection of the light emitting devices in the second region on a plane in which the display panel is located is greater than an area of an orthographic projection of the light emitting devices in the first region on the plane in which the display panel is located;
wherein the first region and the second region are disposed along a first direction, the light emitting devices in the second region are arranged in a quantity N of column sets along the first direction, wherein Nis an integer greater than 1;
wherein along a direction from a location near the signal input terminal to a location away from the signal input terminal, an area of an orthographic projection of the light emitting devices of a (i−1)^{th} one of the column sets on the plane in which the display panel is located is less than an area of an orthographic projection of the light emitting devices of an i^{th} one of the column sets on the plane in which the display panel is located, wherein i is less than or equal to N;
wherein the light emitting device comprises a first light emitting chip, a second light emitting chip, and a third light emitting chip, the first light emitting chip is a red light emitting chip, the second light emitting chip is a green light emitting chip, and the third light emitting chip is a blue light emitting chip; and
wherein an effective light emitting area of the first light emitting chip is greater than an effective light emitting area of the second light emitting chip, and the effective light emitting area of the second light emitting chip is greater than an effective light emitting area of the third light emitting chip.

In an embodiment, the light emitting devices arranged in a quantity M of row sets along a second direction, wherein M is an integer greater than 1, the second direction intersects the first direction; and
along a direction from a location near the signal input terminal to a location away from the signal input terminal, an area of an orthographic projection of the light emitting devices of a (j−1)^{th} one of the row sets on the plane in which the display panel is located is less than an area of an orthographic projection of the light emitting devices of a j^{th} one of the row sets on the plane in which the display panel is located, wherein j is less than or equal to M.

The display panel provided by the embodiment of the present application comprises a pixel region defined in the display panel. The pixel region includes a first region and a second region. The display panel includes a plurality of light emitting devices, a signal input terminal, and a signal connection line. The light emitting devices are disposed in the first region and the second region. The signal input terminal is disposed in the first region, and the signal input terminal is sequentially connected to the light emitting devices of the first region and the light emitting devices of the second region through the signal connection line. Along a direction from a location near the signal input terminal to away from the signal input terminal, because a resistance and a parasitic capacitor exit on the signal connection line, IR drop occurs, the current weakens. Setting an area of an orthographic projection of the light emitting devices of the second region on a plane in which the display panel is located to be greater than an area of an orthographic projection of the light emitting devices of the first region on a plane in which the display panel is located makes the light emitting devices from a location near the signal input terminal to a location away from the signal input terminal can match a current after the IR drop. Thus, the light emitting devices can achieve the same light emitting intensity to improve a uniformity of display brightness.

### DESCRIPTION OF DRAWINGS

FIG. 1 is a schematic top structural view of a display panel provided by an embodiment of the present application;

FIG. 2 is a schematic structural view of light emitting devices of the display panel provided by the embodiment of the present application;

FIG. 3 is a schematic top structural view of the light emitting devices of the display panel provided by the embodiment of the present application;

FIG. 4 is a schematic structural view of light emitting devices of the display panel provided by another embodiment of the present application;

FIG. 5 is a schematic partial top structural view of light emitting devices of the display panel provided by another embodiment of the present application.

### REFERENCE CHARACTERS

display panel 100; pixel region A; first region A1; second region A2; third region A3; light emitting devices 10; signal input terminal 20; signal connection line 30; driver substrate 40; cathode layer 50; cathode wiring 60; anode layer 70;
column sets L; row sets H; first direction X; second direction Y;
first light emitting chip 11; second light emitting chip 12; third light emitting chip 13; first edge S1; second edge S2; third edge S3;
first anode wiring 81; second anode wiring 82; third anode wiring 83;
the via hole K; the first hole wall K1; the second hole wall K2; the third hole wall K3; the fourth hole wall K4.

### DETAILED DESCRIPTION OF PREFERRED EMBODIMENTS

The technical solution in the embodiment of the present application will be clearly and completely described below with reference to the accompanying drawings in the embodiments of the present application. Apparently, the described embodiments are merely some embodiments of the present application instead of all embodiments. According to the embodiments in the present application, all other embodiments obtained by those skilled in the art without making any creative effort shall fall within the protection scope of the present application.

In the description of the present application, it should be understood that terminologies of “center”, “longitudinal”, “transverse”, “length”, “width”, “thickness”, “upper”, “lower”, “front”, “rear”, “left”, “side”, “vertical”, “horizontal”, “top”, “bottom”, “inner”, “outer”, “clockwise”, “counterclockwise” for indicating relations of orientation or position are based on orientation or position of the accompanying drawings, are only for the purposes of facilitating description of the present application and simplifying the description instead of indicating or implying that the referred device or element must have a specific orientation or position, must to be structured and operated with the specific orientation or position. Therefore, they should not be understood as limitations to the present application.

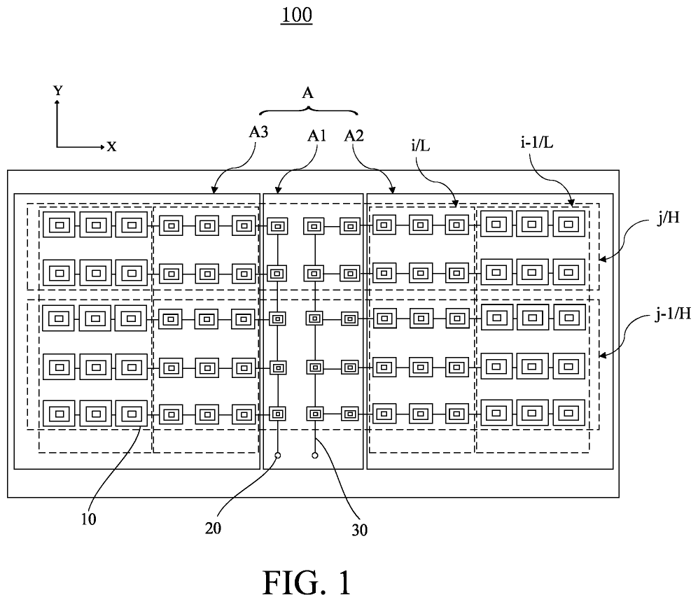

With reference to FIG. 1, a display panel 100 provided by an embodiment of the present application comprises a pixel region A defined in the display panel 100. The pixel region A comprises a first region A1 and a second region A2. The display panel 100 comprises a plurality of light emitting devices 10, a signal input terminal 20, and a signal connection line 30. In particular, the light emitting devices 10 are disposed in the first region A1 and the second region A2. The signal input terminal 20 are disposed in the first region A1. The signal input terminal 20 is sequentially connected to the light emitting devices 10 of the first region A1 and the light emitting devices 10 of the second region A2 through the signal connection line 30. An area of an orthographic projection of the light emitting devices 10 of the second region A2 on a plane in which the display panel 100 is located is greater than an area of an orthographic projection of the light emitting devices 10 of the first region A1 on the plane in which the display panel 100 is located.

In the display panel 100 provided by the embodiment of the present application, the signal input terminal 20 of the display panel 100 is disposed in the first region A1, and the signal input terminal 20 is sequentially connected to the light emitting devices 10 of the first region A1 and the light emitting devices 10 of the second region A2 through the signal connection line 30. Along a direction from a location near the signal input terminal 20 to a location away from the signal input terminal 20, because a resistance and parasitic capacitor existing on the signal connection line 30, IR drop occurs such that the current weakens. Setting an area of an orthographic projection of the light emitting devices 10 of the second region A2 on the plane in which the display panel 100 is located to be greater than an area of an orthographic projection of the light emitting devices 10 of the first region A1 on the plane in which the display panel 100 is located makes the light emitting devices 10 along a direction from a location near the signal input terminal 20 to a location away from the signal input terminal 20 can match the current after the IR drop. Thus, the light emitting devices 10 can achieve the same light emitting intensity to improve uniformity of display brightness of the display panel 100.

In particular, in the present embodiment, the pixel region A comprises a third region A3, the first region A1, and the second region A2 that are disposed sequentially. The third region A3 and the second region A2 are located on two sides of the first region A1. The signal input terminal 20 is disposed in the first region A1, the signal connection line 30 is sequentially connected to the light emitting devices 10 of the first region A1 and the light emitting devices 10 of the second region A2. Similarly, the signal connection line 30 is sequentially connected to the light emitting devices 10 of the first region A1 and the light emitting devices 10 of the third region A3. It can be understood that the second region A2, the third region A3 are disposed on two sides of the first region A1 respectively. Signals are inputted from the first region A1 and are transmitted toward two sides such that decay of currents in the second region A2 and the third region A3 is symmetrical, and sizes of the light emitting devices 10 matching the currents respectively are also symmetrical, which can prevent setting oversized light emitting devices 10 at an over far distance from the signal input terminal 20, and also facilitates a manufacturing process of the light emitting devices 10.

In the present embodiment, the first region A1 and the second region A2 are disposed along a first direction X. The light emitting devices 10 of the second region A2 are arranged in a quantity N of column sets L along the first direction X, and N is an integer greater than 1. Along a direction from a location near the signal input terminal 20 to a location away from the signal input terminal 20, an area of an orthographic projection of the light emitting devices 10 of a (i−1)^{th} one of the column sets L on the plane in which the display panel 100 is located is less than an area of an orthographic projection of the light emitting devices 10 of an i^{th} one of the column sets L on the plane in which the display panel 100 is located, and i is less than or equal to N.

Optionally, the light emitting devices 10 of the second region A2 are arranged in two column sets L, an area of an orthographic projection of the light emitting devices 10 of a first one of the column sets L on the plane in which the display panel 100 is located is less than an area of an orthographic projection of the light emitting devices 10 of a second one of the column sets L on the plane in which the display panel 100 is located. The light emitting devices 10 of the second region A2 can also be arranged in three column sets L, an area of an orthographic projection of the light emitting devices 10 of a first one of the column sets L on the plane in which the display panel 100 is located is less than an area of an orthographic projection of the light emitting devices 10 of a second one of the column sets L on the plane in which the display panel 100 is located. An area of an orthographic projection of the light emitting devices 10 of the second one of the column sets L on the plane in which the display panel 100 is located is less than an area of an orthographic projection of the light emitting devices 10 of a third one of the column sets L on the plane in which the display panel 100 is located. The light emitting devices 10 of the second region A2 can also be arranged in four column sets L, five column sets L, six column sets L, etc., and the present application is not limited thereto.

In particular, each of the column sets L comprises three columns of the light emitting devices 10 extending along a second direction Y. The second direction Y intersects the first direction X. in the same one of the column sets L, difference of influence of the IR drop to the currents is less. Namely, in the same one of the column sets L, currents supplied to the light emitting devices 10 are similar, areas of orthographic projections of the light emitting devices 10 disposed in the same one of the column sets L on the plane in which the display panel 100 is located are equal, which advantages simplification of manufacturing processes for the light emitting devices 10. Optionally, each of the column sets L can comprise one column of the light emitting devices 10, two columns of the light emitting devices 10, four columns of the light emitting devices 10, or five columns of the light emitting devices 10, a specific value of the area of the light emitting device 10 is determined according to the IR drop of each location of the display panel 100.

The light emitting devices 10 of the third region A3 are arranged in a quantity N of column sets L along a direction reverse to the first direction X, and Nis an integer greater than 1. Along a direction from a location near the signal input terminal 20 to a location away from the signal input terminal 20, an area of an orthographic projection of the light emitting devices 10 of a (i−1)^{th} one of the column sets L on the plane in which the display panel 100 is located is less than an area of an orthographic projection of the light emitting devices 10 of an i^{th} one of the column sets L on the plane in which the display panel 100 is located, an i is less than or equal to N.

In the present embodiment, the light emitting devices 10 Y are arranged in a quantity M of row sets H along a second direction, and M is an integer greater than 1. In particular, the signal input terminal 20 is disposed on a side of a first row away from a M^{th} row. Along a direction from a location near the signal input terminal 20 to a location away from the signal input terminal 20, an area of an orthographic projection of the light emitting devices 10 of a (j−1)^{th} one of the row sets H on the plane in which the display panel 100 is located is less than an area of an orthographic projection of the light emitting devices 10 of a j^{th} one of the row sets H on the plane in which the display panel 100 is located, and j is less than or equal to M.

Optionally, the light emitting devices 10 are arranged in two row sets H along the second direction Y, an area of an orthographic projection of the light emitting devices 10 of a first one of the row sets H on the plane in which the display panel 100 is located is less than an area of an orthographic projection of the light emitting devices 10 of the second one of the row sets H on the plane in which the display panel 100 is located. The light emitting devices 10 can also be arranged in three row sets H, an area of an orthographic projection of the light emitting devices 10 of the first one of the row sets H on the plane in which the display panel 100 is located is less than an area of an orthographic projection of the light emitting devices 10 of the second one of the row sets H on the plane in which the display panel 100 is located, and an area of an orthographic projection of the light emitting devices 10 of the second one of the row sets H on the plane in which the display panel 100 is located is less than an area of an orthographic projection of the light emitting devices 10 of the third one of the row sets H on the plane in which the display panel 100 is located. The light emitting devices 10 can also be arranged in four row sets H, five row sets H, six row sets H, and the present application is not limited thereto.

Optionally, in the light emitting devices 10 in the first region, an area of an orthographic projection of the light emitting devices 10 of a (j−1)^{th} one of the row sets H on the plane in which the display panel 100 is located is less than an area of an orthographic projection of the light emitting devices 10 of a j^{th} one of the row sets H on the plane in which the display panel 100 is located, and/or, in the light emitting devices 10 of a second region, an area of an orthographic projection of the light emitting devices 10 of a (j−1)^{th} one of the row sets H on the plane in which the display panel 100 is located is less than an area of an orthographic projection of the light emitting devices 10 of a j^{th} one of the row sets H on the plane in which the display panel 100 is located.

In particular, in the first region, the first one of the row sets H comprises three rows of the light emitting devices 10 extending along the first direction X, and the second one of the row sets H comprises two rows of the light emitting devices 10 disposed along the first direction X. In the same one of the row sets H, difference of influence of the IR drop to currents is less. Namely, currents supplied into the light emitting devices 10 in the same one of the row sets H are similar, and areas for disposing the light emitting devices 10 of the same one of the row sets H are equal, which facilitates simplification of manufacturing processes for the light emitting devices 10. Optionally, one row set H can comprise one row of the light emitting devices 10, four rows of the light emitting devices 10, or five rows of the light emitting devices 10, and the present application has no limit thereto. A specific area of the light emitting device 10 is determined according to the IR drop of each location of the display panel 100.

In the present embodiment, one row set H is at least connected to one signal connection line 30, and currents of the signal connection lines 30 are equal.

It can be understood that equal currents can be supplied into the light emitting devices 10 respectively such that the currents of the signal connection lines 30 can be equal and then sizes of driver thin film transistors transmitting currents to the light emitting devices 10 can be the same, which facilitates manufacturing processes. Namely, under a circumstance of the driver thin film transistors having the same sizes, output currents are equal, and brightness at each location of the display panel 100 is uniform and consistent.

It should be explained that when one row set H comprises one row of the light emitting devices 10, one row set H is connected to two signal connection lines 30, one of the signal connection lines 30 is connected from the light emitting devices 10 of the first region A1 of the row to the second region A2, the other of the signal connection lines 30 is connected from the light emitting devices 10 of the first region A1 of the row to the third region A3. One row set H comprises two rows of the light emitting devices 10, one row set H is connected to four signal connection lines 30. One row of the light emitting devices 10 is connected to two signal connection lines 30. One of the signal connection lines 30 is connected from the light emitting devices 10 of the first region A1 to the second region A2, and the other of the signal connection lines 30 is connected from the light emitting devices 10 of the first region A1 to the third region A3.

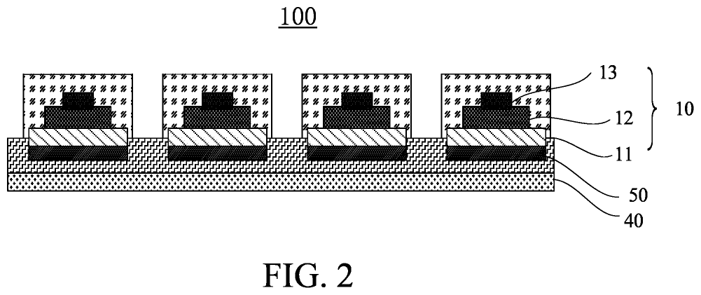

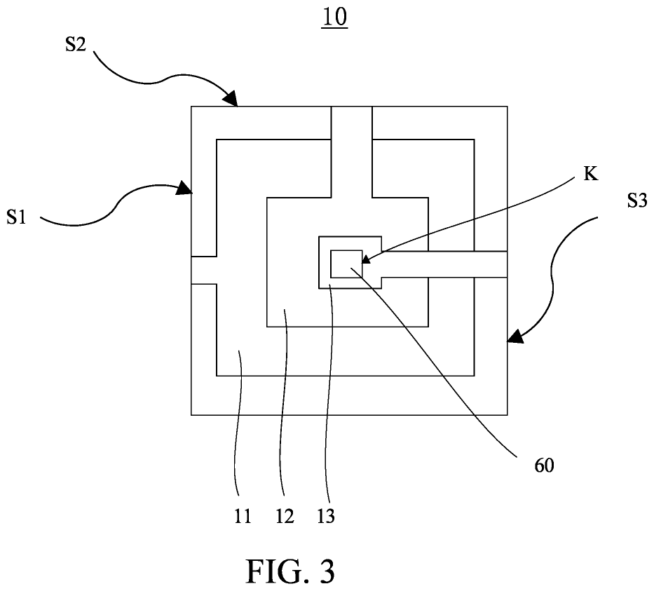

With reference to FIGS. 2 and 3, in the present embodiment, the light emitting device 10 comprises a first light emitting chip 11, a second light emitting chip 12, and a third light emitting chip 13. The first light emitting chip 11 is a red light emitting chip, the second light emitting chip 12 is a green light emitting chip, and the third light emitting chip 13 is a blue light emitting chip. Photoelectric conversion efficiencies of the red light emitting chip, green light emitting chip, and blue light emitting chip are different, the photoelectric conversion efficiency of the blue light emitting chip is higher than the photoelectric conversion efficiency of the green light emitting chip, the photoelectric conversion efficiency of the green light emitting chip is higher than the photoelectric conversion efficiency of the red light emitting chip. Therefore, under circumstance of the same input current, an effective light emitting area of the first light emitting chip 11 is greater than an effective light emitting area of the second light emitting chip 12, the effective light emitting area of the second light emitting chip 12 is greater than an effective light emitting area of the third light emitting chip 13. Namely, an area for disposing the red light emitting chip is greater than that of the green light emitting chip, the area of the green light emitting chip is greater than that of the blue light emitting chip, which can make the red, green, and blue light emitting chips achieve the same light emitting intensity, reduce power consumption, simplify a driver circuit structure. Specific area ratios can be determined according to a current and brightness variation relationship curvature of red, green, and blue light emitting chips.

In the present embodiment, the display panel 100 further comprises a driver substrate 40. The first light emitting chip 11 is disposed on the driver substrate 40. The second light emitting chip 12 is disposed on the first light emitting chip 11. The third light emitting chip 13 is disposed on the second light emitting chip 12. An orthographic projection of the first light emitting chip 11 on the driver substrate 40, an orthographic projection of the second light emitting chip 12 on the driver substrate 40, and an orthographic projection of the third light emitting chip 13 on the driver substrate 40 at least partially overlap one another.

It can be understood that stacking the first light emitting chip 11, the second light emitting chip 12, and the third light emitting chip 13 can extremely reduce a size of the light emitting device 10, one light emitting device 10 is one pixel unit, and therefore the pixel unit can be reduce. In the same display area, more light emitting devices 10 can be disposed to increase the resolution.

In the present embodiment, the display panel 100 further comprises a cathode layer 50 and a cathode wiring 60. The cathode layer 50 is disposed between the driver substrate 40 and the first light emitting chip 11. A via hole K is defined in the light emitting devices 10, and the via hole K penetrates the third light emitting chip 13, the second light emitting chip 12, and the first light emitting chip 11 and exposes the cathode layer 50. The cathode wiring 60 is disposed in the via hole K, and the cathode wiring 60 is connected to the cathode layer 50. A cathode of the first light emitting chip 11, a cathode of the second light emitting chip 12, and a cathode of the third light emitting chip 13 are connected to the cathode wiring 60.

It can be understood that the via hole K is defined in the light emitting devices 10 and penetrates the third light emitting chip 13, the second light emitting chip 12, and the first light emitting chip 11. Setting the via hole K achieves connection between the cathode of the light emitting chip with the cathode layer 50 and facilitates outward extension of the cathode wiring 60, which can be in a simplified connection.

In the present embodiment, the display panel 100 further comprises an anode layer 70, a first anode wiring 81, a second anode wiring 82, a third anode wiring 83. The first anode wiring 81, the second anode wiring 82, the third anode wiring 83 are connected to the anode layer 70.

The light emitting devices 10 comprises a first edge S1, a second edge S2, and a third edge S3. An anode of the first light emitting chip 11 is disposed on the first edge S1 and is connected to the first anode wiring 81. An anode of the second light emitting chip 12 is disposed on the second edge S2 and is connected to the second anode wiring 82. An anode of the third light emitting chip 13 is disposed on the third edge S3 and is connected to the third anode wiring 83.

Optionally, the anode layer 70 and the cathode layer 50 can be disposed insulatively from each other and be disposed in the same layer.

It can be understood that the stacked first light emitting chip 11, second light emitting chip 12, and third light emitting chip 13 disadvantage outward extension of anode wirings. Therefore, disposing an anode of the first light emitting chip 11 on the first edge S1, disposing an anode of the second light emitting chip 12 on the second edge S2, and disposing an anode of the third light emitting chip 13 on the third edge S3 facilitates outward extension of the anode wirings of each light emitting chip without interference causing short circuits.

In particular, the display panel 100 further comprises a the first anode wiring 81, and the second anode wiring 82, the third anode wiring 83, the first anode wiring 81, the second anode wiring 82, the third anode wiring 83 are connected to the anode layer 70. The first anode wiring 81 is deposited and disposed on a stage surface of the first light emitting chip 11 from the first edge S1, and an end of the first anode wiring 81 is connected to the anode layer 70, and another end of the first anode wiring 81 is connected to an anode of the first light emitting chip 11 disposed on the first edge S1. The second anode wiring 82, from the second edge S2, is continuously deposited on a stage surface of the second light emitting chip 12, a sidewall of the second light emitting chip 12, and a stage surface of the first light emitting chip 11. Also, an end of the second anode wiring 82 is connected to the anode layer 70, and another end of the second anode wiring 82 is connected to an anode of the second light emitting chip 12 disposed on the second edge S2. The third anode wiring 83, from the third edge S3, is continuously deposited on a stage surface of the third light emitting chip 13, a sidewall of the third light emitting chip 13, a stage surface of the second light emitting chip 12, a sidewall of the second light emitting chip 12, and a stage surface of the first light emitting chip 11, and an end of the third anode wiring 83 is connected to the anode layer 70, another end of the third anode wiring 83 is connected to an anode of the third light emitting chip 13 disposed on the third edge S3. It should be explained that the stage surface here refers to a surface of light emitting chip away from the driver substrate 40. In the present embodiment, the signal connection line 30 comprises a cathode wiring 60 and an anode wiring.

Optionally, the first light emitting chip 11 is disposed on and protrudes from the first edge S1 of the light emitting devices 10, the second light emitting chip 12 is disposed on and protrudes from the second edge S2, the third light emitting chip 13 is disposed on and protrudes from the third edge S3, anodes are then disposed on the protruding portions respectively, which facilitates anode wirings extending from the edges of the light emitting devices 10.

Optionally, an insulation layer is disposed between the first light emitting chip 11 and the second light emitting chip 12, an insulation layer is disposed between the second light emitting chip 12 and the third light emitting chip 13, which can prevent malfunction of the light emitting chips of each layer due to a short circuit, and prevent a short circuit between the cathode wiring 60 and the anode wiring, and short circuits among the plural anode wirings.

In the present embodiment, the second light emitting chip 12 and the third light emitting chip 13 are transparent chips. Namely, in overlapping portions, light emitted from the first light emitting chip 11 are emitted out through the second light emitting chip 12 and the third light emitting chip 13, and the second light emitting chip 12 would not shield light from the first light emitting chip 11. Similarly, light emitted from the second light emitting chip 12 can be emitted out through the third light emitting chip 13, and the third light emitting chip 13 would not shield light from the second light emitting chip 12.

It can be understood that the second light emitting chip 12 and the third light emitting chip 13 are transparent chip and can further improve a light emitting efficiency of the light emitting devices 10. Also, while effective light emitting areas of the first light emitting chip 11, the second light emitting chip 12, the third light emitting chip 13 are guaranteed, sizes of the light emitting devices 10 are further reduced to further increase a resolution.

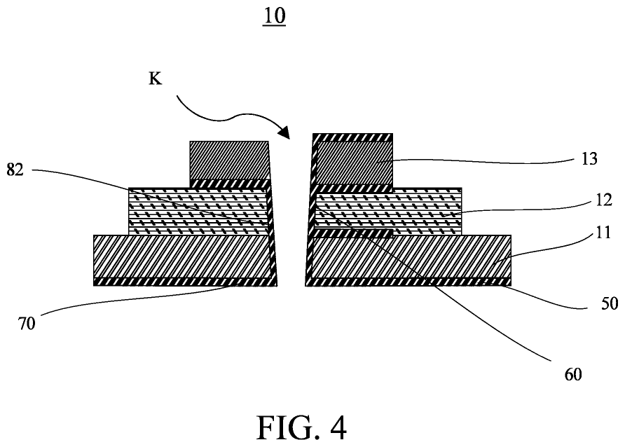

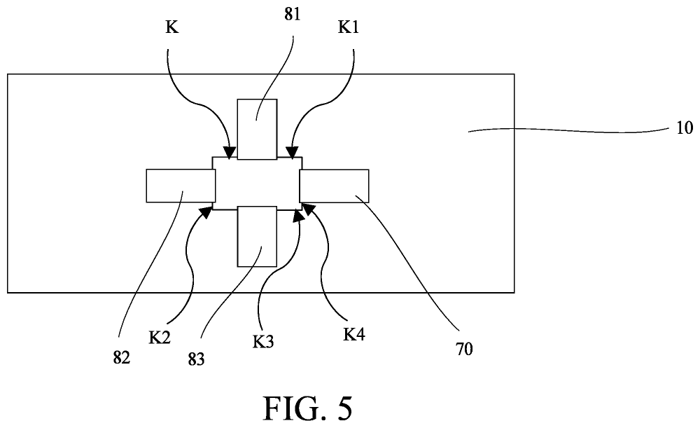

With reference to FIGS. 4 and 5, a difference of the display panel 100 provided by another embodiment of the present application from the above embodiment is that: the first anode wiring 81, the second anode wiring 82, and the third anode wiring 83 are disposed in a different manner. The first anode wiring 81, the second anode wiring 82, and the third anode wiring 83 can also extend out from the via hole K.

A hole wall of the via hole K of the present embodiment at least comprises a first hole wall K1, a second hole wall K2, a third hole wall K3, and a fourth hole wall K4. The first anode wiring 81 is disposed in the first hole wall K1 and is connected to the anode of the first light emitting chip 11. The second anode wiring 82 is disposed in the second hole wall K2 and is connected to the anode of the second light emitting chip 12. The third anode wiring 83 is disposed in the third hole wall K3 and is connected to the anode of the third light emitting chip 13. The cathode wiring 60 is disposed in the fourth hole wall K4.

The present embodiment, by disposing the via hole K, facilitates outward extension of the anode wirings and the cathode wirings 60 of the stacked light emitting chips. Also, disposing the first anode wiring 81, the second anode wiring 82, the third anode wiring 83, and the cathode wiring 60 in the first hole wall K1, the second hole wall K2, the third hole wall K3, the fourth hole wall K4 respectively can prevent malfunction due to contact between wirings.

Optionally, a diameter of the via hole K gradually decreases along a direction from a location away from the driver substrate 40 to a location near the driver substrate 40. Namely, an included angle between planes in which the hole wall and the driver substrate 40 are located respectively is a slant angle greater than 0 and less than 90. Such setting can facilitate deposition of the anode wiring and the cathode wiring 60 without cracks due to an excessive steepness of the slant angle.

The display panel provided by the present application is described in detail as above.

The display panel provided by the embodiment of the present application includes a pixel region defined in the display panel. The pixel region includes a first region and a second region. The display panel includes a plurality of light emitting devices, a signal input terminal, and a signal connection line. The light emitting devices are disposed in the first region and the second region. The signal input terminal is disposed in the first region, and the signal input terminal is sequentially connected to the light emitting devices of the first region and the light emitting devices of the second region through the signal connection line. Along a direction from a location near the signal input terminal to away from the signal input terminal, because a resistance and a parasitic capacitor exit on the signal connection line, IR drop occurs, the current weakens. Setting an area of an orthographic projection of the light emitting devices of the second region on a plane in which the display panel is located to be greater than an area of an orthographic projection of the light emitting devices of the first region on a plane in which the display panel is located makes the light emitting devices from a location near the signal input terminal to a location away from the signal input terminal can match a current after the IR drop. Thus, the light emitting devices can achieve the same light emitting intensity to improve a uniformity of display brightness.

In the present specification, principles and embodiments of the present application are described using specific examples. The explanation of the above embodiments is only intended to assist in understanding the core ideas of the present application. It should be noted that for those skilled in the art in this technical field, various improvements and modifications can be made to the present application without departing from the principles of the present application. These improvements and modifications also fall within the scope of the claims of the present application.

What is claimed is:

1. A display panel, comprising a pixel region defined in the display panel, wherein the pixel region comprises a first region and a second region, and the display panel further comprises:
a plurality of light emitting devices disposed in the first region and the second region;
a signal input terminal disposed in the first region; and
a signal connection line, wherein the signal input terminal is sequentially connected to the light emitting devices in the first region and the light emitting devices in the second region through the signal connection line, an area of an orthographic projection of the light emitting devices in the second region on a plane in which the display panel is located is greater than an area of an orthographic projection of the light emitting devices in the first region on the plane in which the display panel is located.

2. The display panel according to claim 1, wherein
the first region and the second region are disposed along a first direction, the light emitting devices in the second region are arranged in a quantity N of column sets along the first direction, wherein N is an integer greater than 1; and
along a direction from a location near the signal input terminal to a location away from the signal input terminal, an area of an orthographic projection of the light emitting devices of a (i−1)^{th} one of the column sets on the plane in which the display panel is located is less than an area of an orthographic projection of the light emitting devices of an i^{th} one of the column sets on the plane in which the display panel is located, wherein i is less than or equal to N.

3. The display panel according to claim 1, wherein
the light emitting devices arranged in a quantity M of row sets along a second direction, wherein Mis an integer greater than 1, the second direction intersects the first direction; and
along a direction from a location near the signal input terminal to a location away from the signal input terminal, an area of an orthographic projection of the light emitting devices of a (j−1)^{th} one of the row sets on the plane in which the display panel is located is less than an area of an orthographic projection of the light emitting devices of a j^{th} one of the row sets on the plane in which the display panel is located, wherein j is less than or equal to M.

4. The display panel according to claim 3, wherein each of the row sets is at least connected to one of the signal connection lines, and currents of a plurality of the signal connection lines are equal.

5. The display panel according to claim 1, wherein
the light emitting device comprises a first light emitting chip, a second light emitting chip, and a third light emitting chip, the first light emitting chip is a red light emitting chip, the second light emitting chip is a green light emitting chip, and the third light emitting chip is a blue light emitting chip; and
an effective light emitting area of the first light emitting chip is greater than an effective light emitting area of the second light emitting chip, and the effective light emitting area of the second light emitting chip is greater than an effective light emitting area of the third light emitting chip.

6. The display panel according to claim 5, wherein the display panel further comprises a driver substrate, the first light emitting chip is disposed on the driver substrate, the second light emitting chip is disposed on the first light emitting chip [symbol] , the third light emitting chip is disposed on the second light emitting chip, and an orthographic projection of the first light emitting chip on the driver substrate, an orthographic projection of the second light emitting chip on the driver substrate, and an orthographic projection of the third light emitting chip on the driver substrate at least overlap one another.

7. The display panel according to claim 6, wherein the display panel further comprises a cathode layer and a cathode wiring, the cathode layer is disposed between the driver substrate and the first light emitting chip, a via hole is defined in each of the light emitting devices, the via hole penetrates the third light emitting chip, the second light emitting chip, and the first light emitting chip and exposes the cathode layer, the cathode wiring is disposed in the via hole, and the cathode wiring is connected to the cathode layer, and a cathode of the first light emitting chip, a cathode of the second light emitting chip, and a cathode of the third light emitting chip is connected to the cathode wiring.

8. The display panel according to claim 7, wherein
the display panel further comprises an anode layer, a first anode wiring, a second anode wiring, and a third anode wiring, the anode layer and the cathode layer are disposed insulatively from each other in a same layer, and the first anode wiring, the second anode wiring, the third anode wiring are connected to the anode layer; and
the light emitting devices comprises a first edge, a second edge, and a third edge, an anode of the first light emitting chip is disposed on the first edge and is connected to the first anode wiring, an anode of the second light emitting chip is disposed on the second edge and is connected to the second anode wiring, and an anode of the third light emitting chip is disposed on the third edge and is connected to the third anode wiring.

9. The display panel according to claim 7, wherein
the display panel further comprises an anode layer, a first anode wiring, a second anode wiring, and a third anode wiring, the anode layer and the cathode layer are disposed insulatively from each other in a same layer, the first anode wiring, the second anode wiring, and the third anode wiring is connected to the anode layer; and
a hole wall of the via hole at least comprises a first hole wall, a second hole wall, a third hole wall, and a fourth hole wall, the first anode wiring is disposed in the first hole wall and is connected to an anode of the first light emitting chip, the second anode wiring is disposed in the second hole wall and is connected to an anode of the second light emitting chip, the third anode wiring is disposed in the third hole wall and is connected to an anode of the third light emitting chip, and the cathode wiring is disposed in the fourth hole wall.

10. The display panel according to claim 6, wherein in overlapping portions, light emitted from the first light emitting chip is emitted out through the second light emitting chip and the third light emitting chip.

11. A display panel, comprising a pixel region defined in the display panel, wherein the pixel region comprises a first region and a second region, and the display panel further comprises:
a plurality of light emitting devices disposed in the first region and the second region;
a signal input terminal disposed in the first region; and
a signal connection line, wherein the signal input terminal is sequentially connected to the light emitting devices in the first region and the light emitting devices in the second region through the signal connection line, an area of an orthographic projection of the light emitting devices in the second region on a plane in which the display panel is located is greater than an area of an orthographic projection of the light emitting devices in the first region on the plane in which the display panel is located;
wherein the first region and the second region are disposed along a first direction, the light emitting devices in the second region are arranged in a quantity N of column sets along the first direction, wherein N is an integer greater than 1;
wherein along a direction from a location near the signal input terminal to a location away from the signal input terminal, an area of an orthographic projection of the light emitting devices of a (i−1)^{th} one of the column sets on the plane in which the display panel is located is less than an area of an orthographic projection of the light emitting devices of an i^{th} one of the column sets on the plane in which the display panel is located, wherein i is less than or equal to N;
wherein the light emitting devices arranged in a quantity M of row sets along a second direction, wherein M is an integer greater than 1, the second direction intersects the first direction; and
wherein along a direction from a location near the signal input terminal to a location away from the signal input terminal, an area of an orthographic projection of the light emitting devices of a (j−1)^{th} one of the row sets on the plane in which the display panel is located is less than an area of an orthographic projection of the light emitting devices of a j^{th} one of the row sets on the plane in which the display panel is located, wherein j is less than or equal to M.

12. The display panel according to claim 11, wherein each of the row sets is at least connected to one of the signal connection lines, and currents of a plurality of the signal connection lines are equal.

13. The display panel according to claim 11, wherein
the light emitting device comprises a first light emitting chip, a second light emitting chip, and a third light emitting chip, the first light emitting chip is a red light emitting chip, the second light emitting chip is a green light emitting chip, and the third light emitting chip is a blue light emitting chip; and
an effective light emitting area of the first light emitting chip is greater than an effective light emitting area of the second light emitting chip, and the effective light emitting area of the second light emitting chip is greater than an effective light emitting area of the third light emitting chip.

14. The display panel according to claim 13, wherein the display panel further comprises a driver substrate, the first light emitting chip is disposed on the driver substrate, the second light emitting chip is disposed on the first light emitting chip [symbol] , the third light emitting chip is disposed on the second light emitting chip, and an orthographic projection of the first light emitting chip on the driver substrate, an orthographic projection of the second light emitting chip on the driver substrate, and an orthographic projection of the third light emitting chip on the driver substrate at least overlap one another.

15. The display panel according to claim 14, wherein the display panel further comprises a cathode layer and a cathode wiring, the cathode layer is disposed between the driver substrate and the first light emitting chip, a via hole is defined in each of the light emitting devices, the via hole penetrates the third light emitting chip, the second light emitting chip, and the first light emitting chip and exposes the cathode layer, the cathode wiring is disposed in the via hole, and the cathode wiring is connected to the cathode layer, and a cathode of the first light emitting chip, a cathode of the second light emitting chip, and a cathode of the third light emitting chip is connected to the cathode wiring.

16. The display panel according to claim 15, wherein
the display panel further comprises an anode layer, a first anode wiring, a second anode wiring, and a third anode wiring, the anode layer and the cathode layer are disposed insulatively from each other in a same layer, and the first anode wiring, the second anode wiring, the third anode wiring are connected to the anode layer; and
the light emitting devices comprises a first edge, a second edge, and a third edge, an anode of the first light emitting chip is disposed on the first edge and is connected to the first anode wiring, an anode of the second light emitting chip is disposed on the second edge and is connected to the second anode wiring, and an anode of the third light emitting chip is disposed on the third edge and is connected to the third anode wiring.

17. The display panel according to claim 15, wherein
the display panel further comprises an anode layer, a first anode wiring, a second anode wiring, and a third anode wiring, the anode layer and the cathode layer are disposed insulatively from each other in a same layer, the first anode wiring, the second anode wiring, and the third anode wiring is connected to the anode layer; and
a hole wall of the via hole at least comprises a first hole wall, a second hole wall, a third hole wall, and a fourth hole wall, the first anode wiring is disposed in the first hole wall and is connected to an anode of the first light emitting chip, the second anode wiring is disposed in the second hole wall and is connected to an anode of the second light emitting chip, the third anode wiring is disposed in the third hole wall and is connected to an anode of the third light emitting chip, and the cathode wiring is disposed in the fourth hole wall.

18. The display panel according to claim 14, wherein in overlapping portions, light emitted from the first light emitting chip is emitted out through the second light emitting chip and the third light emitting chip.

19. A display panel, comprising a pixel region defined in the display panel, wherein the pixel region comprises a first region and a second region, and the display panel further comprises:
a plurality of light emitting devices disposed in the first region and the second region;
a signal input terminal disposed in the first region; and
a signal connection line, wherein the signal input terminal is sequentially connected to the light emitting devices in the first region and the light emitting devices in the second region through the signal connection line, an area of an orthographic projection of the light emitting devices in the second region on a plane in which the display panel is located is greater than an area of an orthographic projection of the light emitting devices in the first region on the plane in which the display panel is located;
wherein the first region and the second region are disposed along a first direction, the light emitting devices in the second region are arranged in a quantity N of column sets along the first direction, wherein Nis an integer greater than 1;
wherein along a direction from a location near the signal input terminal to a location away from the signal input terminal, an area of an orthographic projection of the light emitting devices of a (i−1)^{th} one of the column sets on the plane in which the display panel is located is less than an area of an orthographic projection of the light emitting devices of an i^{th} one of the column sets on the plane in which the display panel is located, wherein i is less than or equal to N;
wherein the light emitting device comprises a first light emitting chip, a second light emitting chip, and a third light emitting chip, the first light emitting chip is a red light emitting chip, the second light emitting chip is a green light emitting chip, and the third light emitting chip is a blue light emitting chip; and
wherein an effective light emitting area of the first light emitting chip is greater than an effective light emitting area of the second light emitting chip, and the effective light emitting area of the second light emitting chip is greater than an effective light emitting area of the third light emitting chip.

20. The display panel according to claim 19, wherein
the light emitting devices arranged in a quantity M of row sets along a second direction, wherein Mis an integer greater than 1, the second direction intersects the first direction; and
along a direction from a location near the signal input terminal to a location away from the signal input terminal, an area of an orthographic projection of the light emitting devices of a (j−1)^{th} one of the row sets on the plane in which the display panel is located is less than an area of an orthographic projection of the light emitting devices of a j^{th} one of the row sets on the plane in which the display panel is located, wherein j is less than or equal to M.
